(19) United States
(12) Patent Application Publication
(10) Pub. No.: US 2015/0328707 A1
(43) Pub. Date: Nov. 19, 2015

(54) SOLDER BALL ATTACHING APPARATUS AND METHOD OF MANUFACTURING THE SAME

(71) Applicants: GWANGSICK KIM, Asan-si (KR); SOOYEOL PARK, Cheonan-si (KR); JaeYong PARK, Cheonan-si (KR)

(72) Inventors: GWANGSICK KIM, Asan-si (KR); SOOYEOL PARK, Cheonan-si (KR); JaeYong PARK, Cheonan-si (KR)

(21) Appl. No.: 14/714,238

(22) Filed: May 15, 2015

(30) Foreign Application Priority Data
May 19, 2014 (KR) 10-2014-0059801
Jul. 21, 2014 (KR) 10-2014-0091969

(51) Int. Cl. B23K 3/06; H05K 3/34

(52) U.S. Cl. CPC B23K 3/0623; H05K 3/34; H05K 2203/041

(57) ABSTRACT

Provided are a solder ball attaching apparatus, a method of manufacturing the same, and a solder ball attaching method using the method. The solder ball attaching apparatus includes a housing, a porous plate on a bottom surface of the housing, a mask pattern on a bottom surface of the porous plate and having holes which provide spaces for temporarily storing solder balls, and a vacuum unit providing a vacuum force to the porous plate.

### CROSS-REFERENCE TO RELATED APPLICATIONS

This U.S. non-provisional patent application claims priority under 35 U.S.C. §119 of Korean Patent Application Nos. 10-2014-0059801, filed on May 19, 2014 and 10-2014-0091969, filed on Jul. 21, 2014, the entire contents of which are hereby incorporated by reference.

### BACKGROUND

The present disclosure herein relates to an apparatus for manufacturing a package, a method of manufacturing the same, and a method of manufacturing a semiconductor package using the same, and more particularly, to a solder ball attaching apparatus, a method of manufacturing the same and an apparatus for attaching a solder ball using the same.

A semiconductor device is an essential element in the electronic industry. With the rapid development of the electronic industry, there is a growing need for a highly-integrated, multifunctional and small-size semiconductor device. This is also true in the case of a semiconductor package. For example, since pads formed on a semiconductor substrate such as a printed circuit board (PCB) are highly integrated, the number of the pads is significantly increasing and intervals therebetween are significantly narrowing. In particular, as the number of solder balls increases, the cost of consumables in a solder ball attaching apparatus increases.

### SUMMARY

The present disclosure provides a solder ball attaching apparatus for attaching solder balls in a highly-integrated semiconductor package at a low cost.

The present disclosure also provides a method of manufacturing the solder ball attaching apparatus.

The present disclosure also provides a method of attaching the solder ball by using the apparatus.

The technical tasks of the present disclosure are not limited to the above-mentioned technical tasks and other technical tasks not mentioned may be clearly understood by a person skilled in the art from the following descriptions.

Embodiments of the inventive concept provide solder ball attaching apparatuses include: a porous plate; and a mask pattern on a surface of the porous plate and having holes which provide spaces storing solder balls temporarily.

In some embodiments, the porous plate may include pores having a size of about 1 μm to about 50 μm.

In other embodiments, the porous plate may include pores having a size of about 10 μm to about 15 μm.

In still other embodiments, the porous plate may include pores having a substantially uniform size.

In even other embodiments, the porous plate may include at least one of zeolite, cement, ceramic, porous plastic, and porous metal.

In yet other embodiments, the mask pattern may be removably coupled to the porous plate.

In further embodiments, a size of each of the holes of the mask pattern may be substantially the same as or larger than a size of each of the solder balls.

In other embodiments of the inventive concept, solder ball attaching apparatuses include: a housing; a porous plate on a bottom surface of the housing; a mask pattern on a bottom surface of the porous plate and having holes which provide spaces for temporarily storing solder balls; and a vacuum unit for providing a vacuum force to the porous plate.

In some embodiments, the porous plate may be removably coupled to the housing and the mask pattern may be removably coupled to the porous plate.

In other embodiments, the porous plate may include pores having a size of about 10 μm to about 15 μm.

In still other embodiments, the housing may include: nozzles in the housing; each of the nozzles having one end opening to the porous plate; and a common line communicating with another end of the nozzles.

In even other embodiments, the vacuum unit may include: a vacuum pump; a vacuum line connecting the vacuum pump to the common line; and a vacuum valve on the vacuum line.

In yet other embodiments, the solder ball attaching apparatuses may further include a control unit connected to the vacuum valve and controlling opening and closing of the vacuum valve.

In further embodiments, the solder ball attaching apparatuses may further include a spray unit providing air or water to the porous plate.

In still further embodiments, the spray unit may include: a fan; a spray line connecting the fan to the common line; and a spray valve on the spray line.

In even further embodiments, the solder ball attaching apparatuses may further include a control unit connected to the spray valve and controlling opening and closing of the spray valve.

In yet further embodiments, the solder ball attaching apparatuses may further include a control unit connected to the spray unit and the vacuum unit to remove the spray unit and the vacuum unit.

In still other embodiments, methods of manufacturing a solder ball attaching apparatus include: coupling an attachable and detachable (removable) porous plate to a bottom surface of a housing connected to a vacuum unit; and coupling an attachable and detachable (removable) mask pattern to a bottom surface of the porous plate.

In some embodiments, the mask pattern may be implemented by forming a plurality of holes in a mask layer by using light amplification by stimulated emission of radiation (LASER).

In other embodiments, the mask layer may include stainless steel.

### BRIEF DESCRIPTION OF THE DRAWINGS

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1A is a perspective view of a solder ball attaching apparatus according to an embodiment of the inventive concepts;

FIG. 1B is a cross-sectional view taken along I-I′ of the solder ball attaching apparatus in FIG. 1A;

FIG. 1C is an enlarged view of portion A of the solder ball attaching apparatus in FIG. 1B according to one embodiment;

FIG. 1D is an enlarged view of portion A of the solder ball attaching apparatus in FIG. 1B according to another embodiment;

FIG. 2A is a plan view of a nozzle structure according to an embodiment of the inventive concepts;

FIG. 2B is a cross-sectional view taken along I-I′ of the nozzle in FIG. 2A;

FIG. 3A is a plan view of a nozzle structure according to another embodiment of the inventive concepts;

FIG. 3B is a cross-sectional view taken along I-I′ of the nozzle in FIG. 3A;

FIG. 4A is a cross-sectional view of a mask pattern according to an embodiment of the inventive concepts;

FIG. 4B is a cross-sectional view of a mask pattern according to an embodiment of the inventive concepts; and

FIGS. 5A through 5D are cross-sectional views illustrating a solder ball attaching process according to an embodiment of the inventive concepts.

### DETAILED DESCRIPTION OF THE EMBODIMENTS

The above objectives, other objectives, characteristics and advantages of the inventive concept will be easily understood through the following embodiments to be described with reference to the accompanying drawings. However, the inventive concept is not limited embodiments to be described below but may be implemented in other forms. On the contrary, exemplary embodiments introduced herein are provided to make disclosed contents thorough and complete and to sufficiently transfer the spirit of the inventive concept to a person skilled in the art.

In the present disclosure, when a component is described as being “on” another component, it means that the component may be formed directly on the other component, or a third component may be arranged in between the components. Also, the thickness of components in the drawings may be exaggerated for clarity.

Embodiments in the present disclosure are described with reference to ideal, exemplary views of the inventive concept that are cross sectional views and/or plan views. The thicknesses of layers and regions in the drawings are exaggerated for the effective description of technical content. Thus, the forms of exemplary views may vary depending on manufacturing technologies and/or tolerances. Thus, embodiments of the inventive concept are not limited to shown specific forms and also include variations in form produced according to manufacturing processes. For example, an etch region shown as a rectangular shape may have a round shape or a shape having a certain curvature. Thus, regions illustrated in the drawings have attributes and the shapes of the regions illustrated in the drawings are intended to illustrate the specific shapes of the regions of elements and not to limit the scope of the inventive concept. Although the terms a first, a second, a third, etc. are used in various embodiments of the present disclosure in order to describe various components, these components are not limited by these terms. These terms are only used in order to distinguish a component from another. Embodiments that are described and illustrated herein also include their complementary embodiments.

The terms used herein are only for explaining embodiments, not limiting the present invention. The terms in a singular form in the disclosure may also include plural forms unless otherwise specified. The term ‘comprises’ and/or ‘comprising’ used in the disclosure does not exclude the existence or addition of other components.

Various embodiments of the inventive concept are described below in detail with reference to the accompanying drawings.

Solder balls are used in various to form a semiconductor package as external terminals. A solder ball attaching apparatus is typically used to pick up solder balls and to attach the picked-up solder balls to, e.g., a substrate such as a printed circuit board (PCB) or another package, for example, to form a package-on-package (POP) package. Hereinafter, the solder ball attaching device is described in more detail. In particular, while the following embodiments exemplarily describe that solder balls are respectively attached to a plurality of pads on a substrate, the inventive concept is not limited thereto.

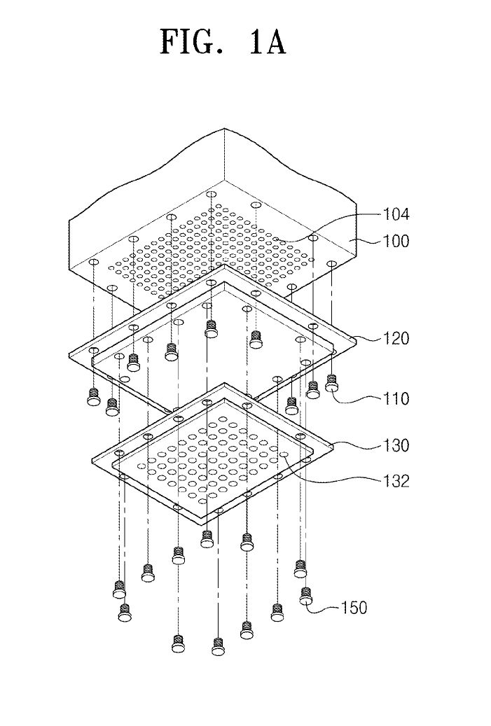

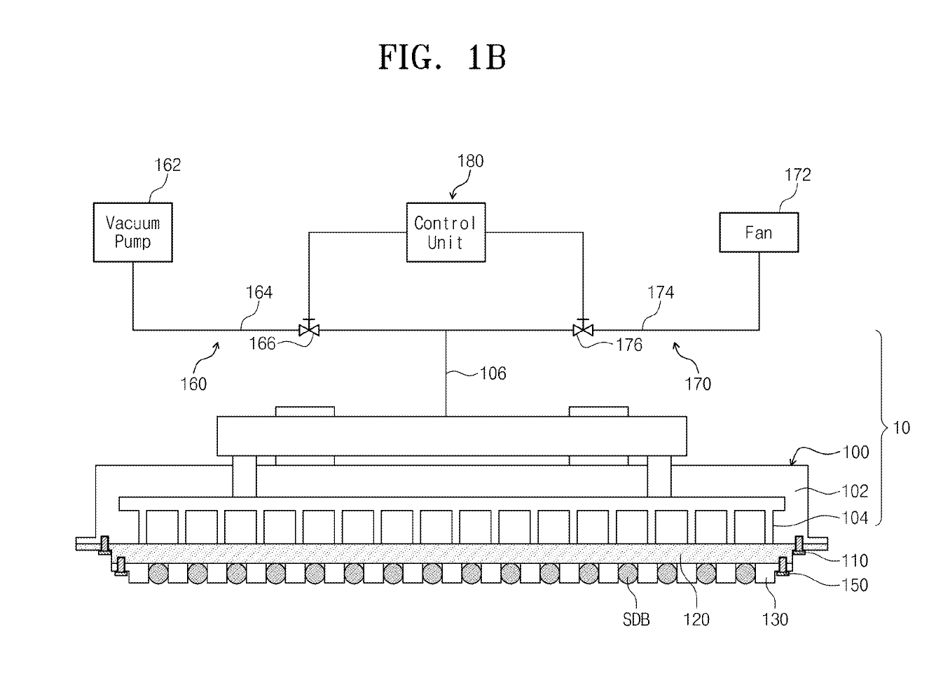

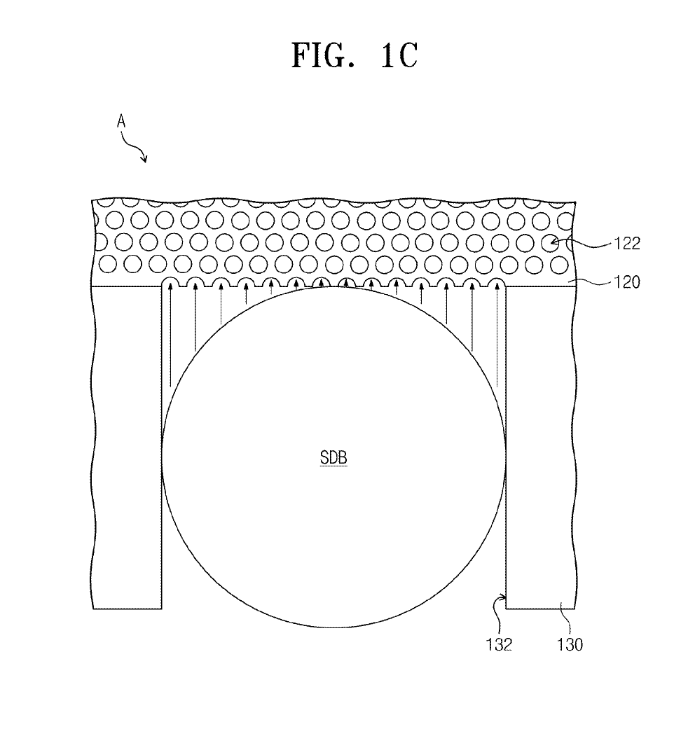

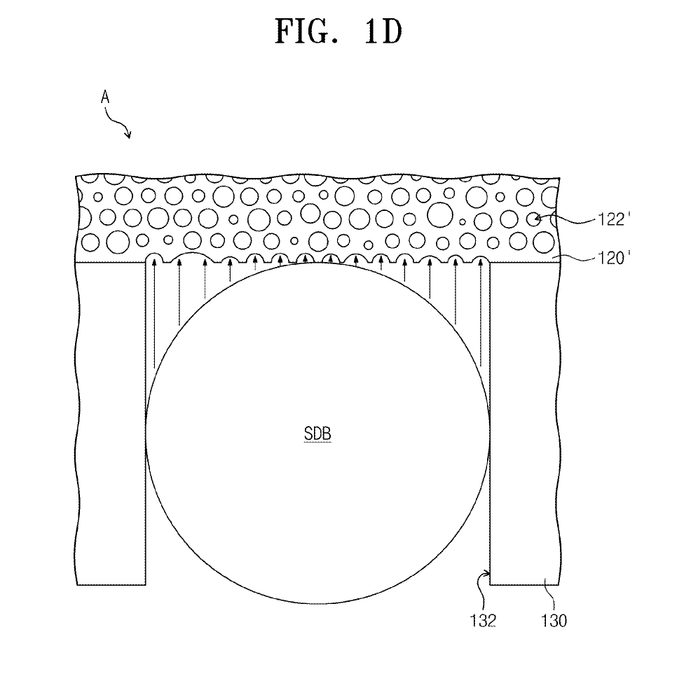

FIG. 1A is a perspective view of a solder ball attaching apparatus according to an embodiment of the inventive concepts, FIG. 1B is a cross-sectional view taken along line I-I′ of the solder ball attaching apparatus shown in FIG. 1A, and FIG. 1C is an enlarged view of portion A of the solder ball attaching apparatus in FIG. 1B according to one embodiment. FIG. 1D is an enlarged view of portion A of the solder ball attaching apparatus in FIG. 1B according to another embodiment different from the embodiment shown in FIG. 1C.

Referring to FIGS. 1A and 1B, a solder ball attaching device 10 may include a housing 100, a porous plate 120, a mask pattern 130, and a vacuum unit 160.

The housing 100 may include a body 102, a common line 106 connected to the outside (externally) and a plurality of nozzles 104 in communication with the common line 106. For example, the body 102 may have a substantially quadrilateral cross-section. The common line 106 may be connected to an external unit such as a vacuum unit 160. Each of the nozzles 104 may include one end communicating with the common line 106 and another end opening toward the lower part of the body 102.

The porous plate 120 may be disposed adjacent to the bottom surface of the body 102 and be in contact with the nozzles 104.

In one embodiment, the porous plate 120 may include pores having substantially the same size and the pores may be arranged in the porous plate 120 at substantially regular intervals as shown in FIG. 1C. According to an embodiment of the inventive concepts, the porous plate 120 may include pores 122 (FIG. 1C) having a size of from about 2 μm to about 50 μm, or more particularly, from about 10 μm to about 15 μm. The porous plate 120 may include at least one of zeolite, cement, ceramic, porous plastic, and porous metal.

In some embodiments, as shown in FIG. 1D, a porous plate 120′ may have pores 122′ having various (or different) sizes therein while the porous plate 120 shown in FIG. 1C may have pores 122 having substantially the same size. Also, in some embodiments, the pores may be arranged in the porous plate 120 at irregular intervals within the spirit and scope of the present disclosure.

The other ends of the nozzles 104 may communicate with the pores 122 of the porous plate 120. The present embodiment may employ the nozzles 104 having various structures. The structure of the nozzles 140 according to one embodiment is described in detail below.

The porous plate 120 and the body 102 may be coupled by a first coupling unit 110. According to an embodiment, the first coupling unit 110 may include a bolt that couples an edge of the porous plate 120 to an edge of the body 102. In some embodiments, the first coupling unit 110 is not limited to the structure shown in the drawings and may have any other suitable structure if the first coupling unit 110 can removably couple the porous plate 120 and the body 102.

The mask pattern 130 may be disposed adjacent to a bottom surface of the porous plate 120. The mask pattern 130 may include stainless steel. The mask pattern 130 may be completed by forming holes 132 (FIG. 1A) on a targeted portion of a mask layer with light amplification by stimulated emission of radiation (LASER). The holes 132 may provide a space in which solder balls SDBs are temporarily stored. Thus, the size of the holes 132 may be substantially the same or larger than that of the solder ball SDB.

The semiconductor package may be expanded depending on the thickness of a mounted chip or the type of molding material. In particular, when a substrate on which the pads are formed are expanded, the location of the solder balls SDBs attached to the pads moves depending on the location of the pads on the expanded substrate. Thus, since the mask pattern 130 according to an embodiment has the holes 132 formed on a targeted location, the solder balls SDBs may be accurately located on the pads.

Also, when the arrangement of the pads 310 is changed, it is possible to easily modify the mask pattern 130 to include hole locations that correspond to the locations of the pads. As needed, the mask pattern 130 may be replaced by another mask pattern having another arrangement of holes 132.

The mask pattern 130 and the porous plate 120 may be coupled by a second coupling unit 150. In some embodiments, the second coupling unit 150 may include a bolt that couples an edge of the porous plate 120 to an edge of the mask pattern 130. In some embodiments, the second coupling unit 150 is not limited to the structure shown in the drawings and may have any other suitable structure if the second coupling unit 150 can removably couple the porous plate 120 and the mask pattern 130.

According to some embodiments, the cross section of the mask pattern 130 may have various structures. The cross section of the mask pattern 130 is described below in more detail.

The vacuum unit 160 may include a vacuum pump 162 providing a vacuum force to the housing 100, a vacuum line 164 connecting the housing 100 to the vacuum pump 162, and a vacuum valve 166 disposed on the vacuum line 164. The vacuum line 164 may communicate with the nozzles 104.

The nozzles 104, the pores 122 in the porous plate 120, and the holes 132 of the mask pattern 130 may communicate with one another. Thus, when the vacuum pump 162 operates, a vacuum force is provided to each of the pores 122 in the porous plate 120 and to the holes 132 of the mask patterns 130. And the solder balls SDBs may be respectively adsorbed in the holes 132 by the vacuum force.

After the solder balls SDBs adsorbed in the solder ball attaching apparatus are aligned on the pads of the substrate, it is possible to detach or release the solder balls SDBs from the solder ball attaching apparatus by removing the vacuum force.

In this case, since the plurality of pores 122 may be formed at substantially regular intervals in the porous plate 120, the amount of vacuum force provided respectively to the holes 132 of the mask pattern 130 may be substantially equal to each other. Also, referring to FIG. 1C, the amount of vacuum force transferred to the solder ball SDB may be substantially uniform across the hole 132. In this regard, in FIG. 1D, the pores 122′ may be formed and arranged in such a way that the amount of vacuum force transferred to the solder ball SDB may still be substantially uniform across the hole 132.

After the vacuum force is removed, the separation of each of the solder balls SDBs from the solder ball attaching apparatus 10 may also be substantially the same. Also, when the uniform vacuum force transferred to the solder ball SDB is removed, a vertical drop may be easier. Thus, it is possible to substantially prevent the solder ball SDB from being attached to any portion other than a targeted pad.

According to an embodiment of the inventive concepts, the solder ball attaching apparatus 10 may further include a spray unit 170. The spray unit 170 may include a fan 172 providing air or water to the body 102, a spray line 174 connecting the fan 172 to the body 102, and a spray valve 176 disposed on the spray line 174.

The spray line 174 may be coupled to the common line 106. For example, the common line 106 may have two branch lines, which may be the vacuum line 164 and the spray line 174, respectively.

According to an embodiment, it is possible to blow air to each of the solder balls SDBs stored in the hole 132 of the mask patterns 130 by using the spray unit 170. Using the air transferred to each of the solder balls SDBs, it is possible to push the solder ball SDB downwardly.

In another embodiment, it is possible to remove foreign materials remaining in the holes 132 of the mask pattern 130 or on the substrate by using the spray unit 170. When it is required to remove the foreign materials remaining on the substrate, the removal operation may be performed after the separation of the mask pattern 130 from the body 102.

According to an embodiment of the inventive concepts, the solder ball attaching apparatus 10 may further include a control unit 180. The control unit 180 may control the vacuum unit 160 and/or the spray unit 170. In more detail, the control unit 180 may be connected to the vacuum valve 166 and the spray valve 176 to control the vacuum valve 166 and the spray valve 176 and thus adsorb and detach the solder balls SDBs stored in the holes 132 of the mask pattern 130.

Hereinafter, the structure of the nozzles 104 of the solder ball attaching apparatus 10 described in FIGS. 1A and 1B is described below in more detail.

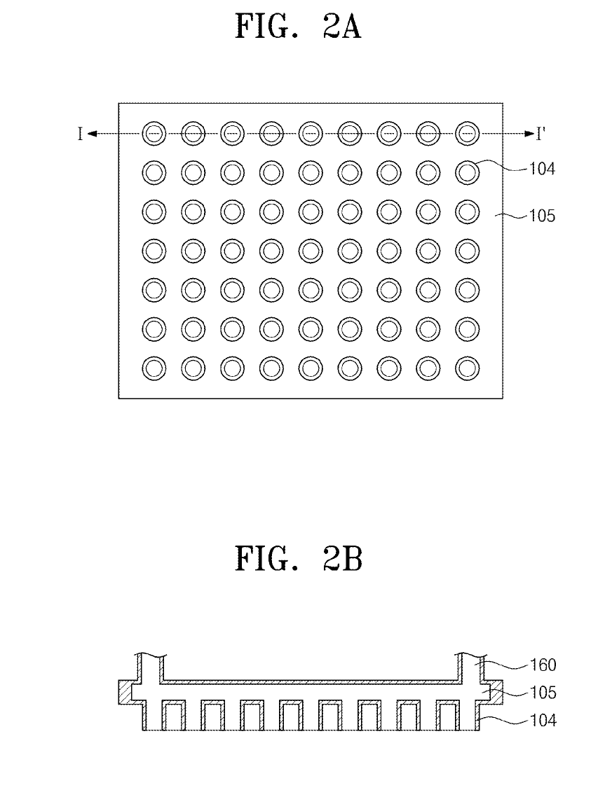

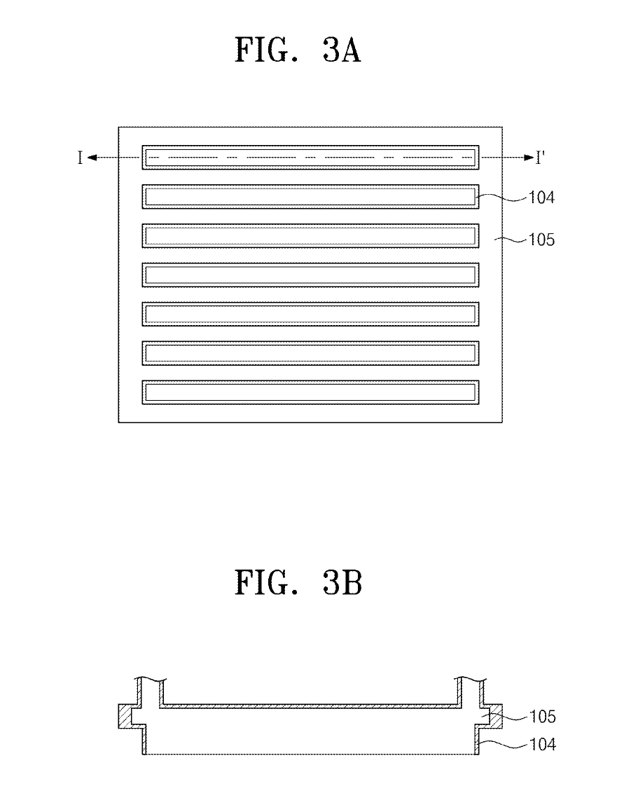

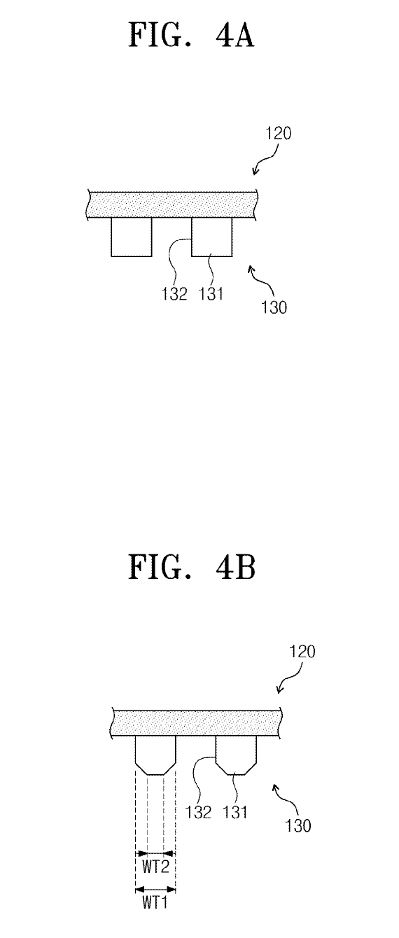

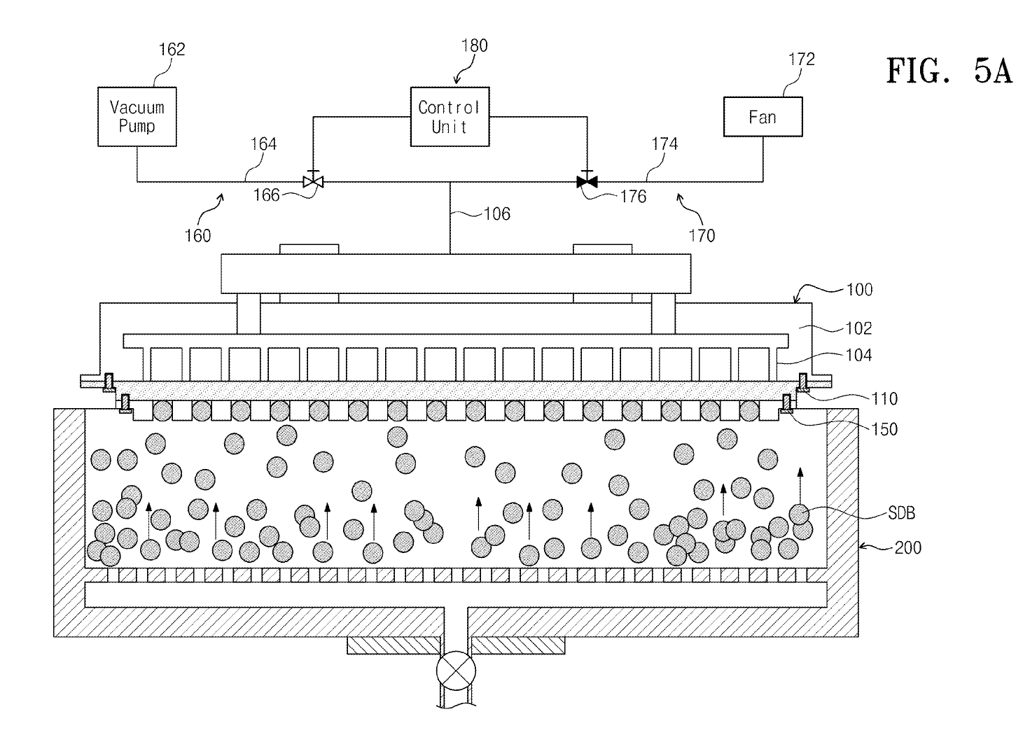

FIG. 2A is a plan view of a nozzle structure according to an embodiment of the inventive concepts and FIG. 2B is a cross-sectional view taken along line I-I′ of the nozzle in FIG. 2A. FIG. 3A is a plan view of a nozzle structure according to another embodiment of the inventive concepts and FIG. 3B is a cross-sectional view taken along line I-I′ of the nozzle in FIG. 3A. FIGS. 2A and 3A are plan views of bottom surfaces of the housing 100.

Referring to FIGS. 1B, 2A, 2B, 3A and 3B, the common line 106 may communicate with the nozzles 104. For example, the common line 106 may branch into two lines in the housing 100. The common line 106 branching into the two lines may communicate with the nozzles 104 through a nozzle connection unit 105. As an example, the nozzle connection unit 105 may have a plate shape. The nozzles 104 may have a structure communicating with a surface of the nozzle connection unit 105 having the plate shape.

Referring to FIGS. 2A and 2B, each of the nozzles 104 may have a substantially cylinder shape and one end of the nozzle has a structure opening toward the porous plate 120 and the other end of the nozzle may communicate with the nozzle connection unit 105. The nozzles 104 may be arranged at substantially regular intervals from one another in a matrix structure.

Referring to FIGS. 3A and 3B, each of the nozzles 104 may have a substantially line shape extended in one direction and one end of the nozzle may have a structure opening to the porous plate 120 and the other end of the nozzle may communicate with the nozzle connection unit 105. For example, the nozzles 104 may have a substantially line shape extended in the longer-length direction of the body 102. In some embodiments, the nozzles 104 may have a substantially line shape extended in the shorter-length direction of the body 102.

Although the present embodiments describe the structure of the nozzle 104, the nozzle 104 of the inventive concept is not limited thereto.

Hereinafter, the structure of the mask pattern 130 of the solder ball attaching apparatus described in FIGS. 1A and 1B is described in more detail.

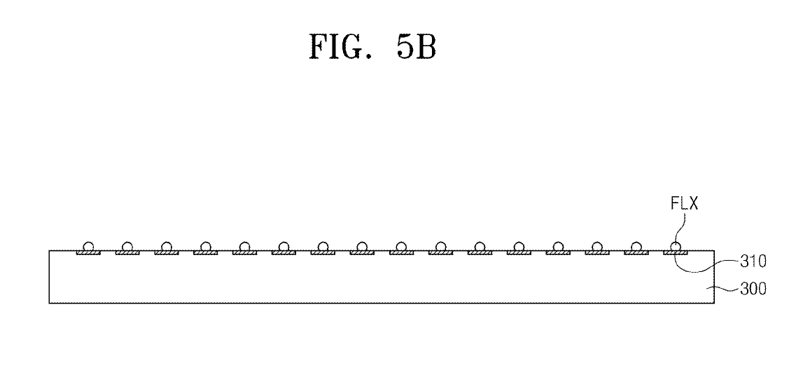

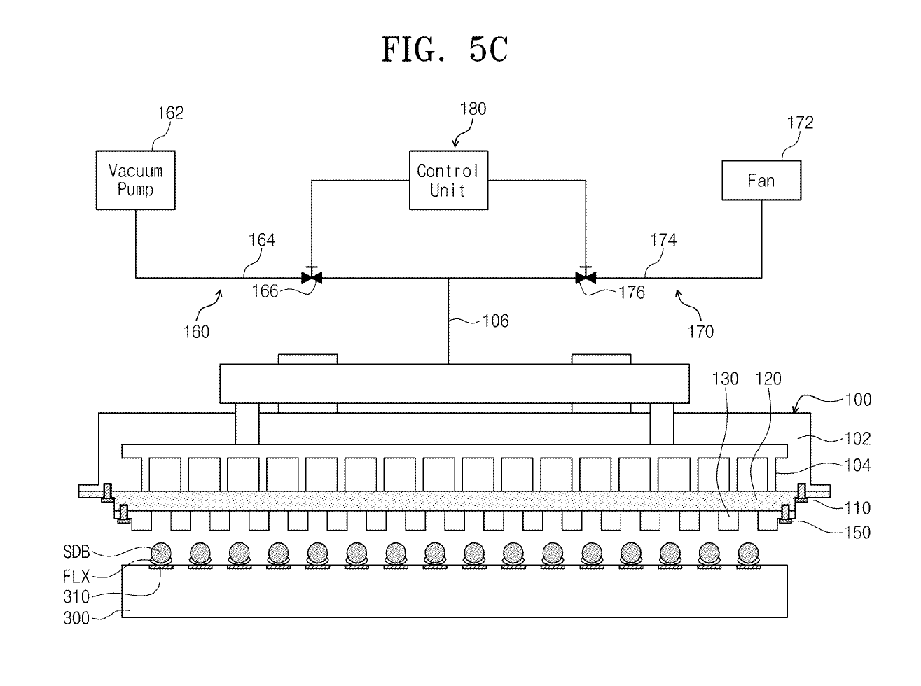

FIG. 4A is a cross-sectional view of a mask pattern according to an embodiment of the inventive concepts, and FIG. 4B is a cross-sectional view of a mask pattern according to an embodiment of the inventive concepts.

Referring to FIG. 4A, the mask pattern 130 may include patterns 131 defining the hole 132. The side surface of each of the patterns 131 of the mask pattern 130 may be substantially perpendicular to the bottom surface of the porous plate 120.

Referring to FIG. 4B, each of the patterns 131 of the mask pattern 130 may include an upper portion having a first width WT1 and a lower portion having a second width WT2 smaller than the first width WT1. An upper width of the hole 132 between the two adjacent patterns 131 may be smaller than a lower width thereof. Since the lower distance of the hole 132 is longer, the solder ball SDB (see FIG. 1B) may be more easily adsorbed into the hole 132.

Although the present embodiments describe the structure of the mask pattern 130, the structure of the mask pattern 130 of the inventive concept is not limited thereto.

Hereinafter, a method of attaching solder balls on pads of a substrate by using the solder ball attaching apparatus is simply described.

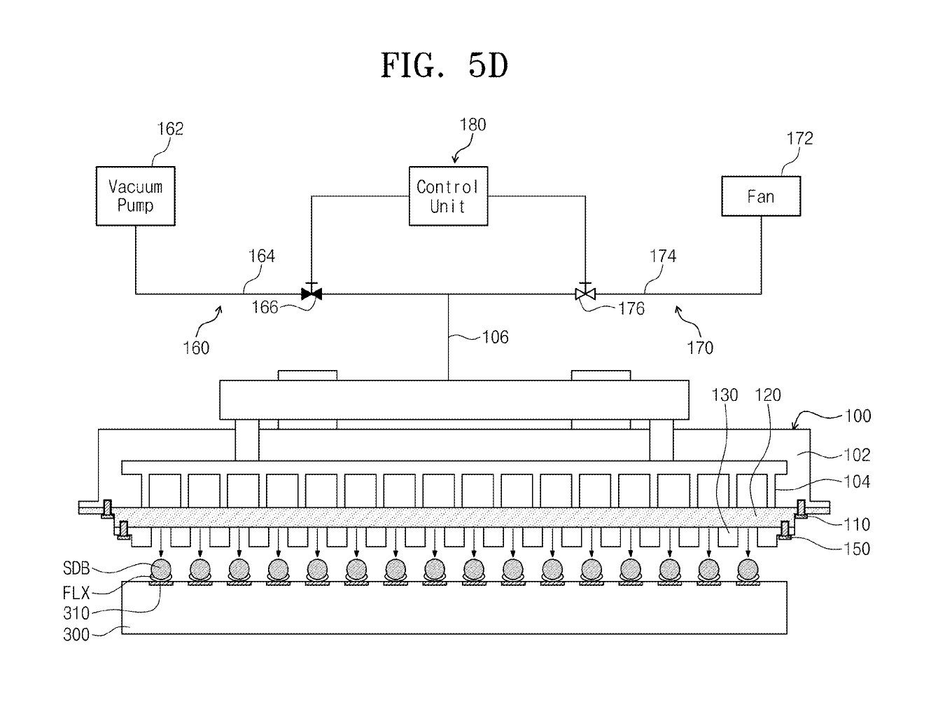

FIGS. 5A through 5D are cross-sectional views illustrating a solder ball attaching process according to an embodiment of the inventive concepts.

Referring to FIG. 5A, the solder balls SDBs may be adsorbed to the solder ball attaching apparatus 10 from a storage unit storing the solder balls SDBs by using the solder ball attaching apparatus.

By operating the vacuum unit 160 of the solder ball attaching apparatus 10, a vacuum force may be provided to the holes 132 of the mask pattern 130. In more detail, the control unit 180 of the solder ball attaching apparatus 10 may open the vacuum valve 166 and close the spray valve 176 to provide a vacuum force to the vacuum line 164, the common line 106, the nozzle 104, the pores 122 of the porous plate 120, and the holes 132. The solder balls SDBs may be respectively adsorbed to the holes 132 by the vacuum force.

Referring to FIG. 5B, the solder ball attaching apparatus 10 to which the solder balls SDBs have been adsorbed may be moved to a substrate 300 on which pads 310 are formed. Flux FLX may be dotted on the pads 310, respectively.

Referring to FIGS. 5C and 5D, each of the solder balls SDBs may be detached from the solder ball attaching apparatus 10 and moved or placed onto the pads 310.

According to FIG. 5C of an embodiment, the control unit 180 of the solder ball attaching apparatus 10 may close the vacuum valve 166 to remove the vacuum from the vacuum line 164, the common line 106, the nozzle 104, the pores 122 of the porous plate 120, and the holes 132. The solder balls SDBs adsorbed to the holes 132 may vertically drop when the vacuum force is removed. As described above, the vacuum force provided to solder ball SDB is created using the plurality of pores 122 and thus may be substantially uniform on the surface of the solder ball SDB. Thus, since the solder ball SDB may substantially, vertically drop when a uniform vacuum is removed, the solder ball SDB may be accurately located on a targeted one of the pads 310.

As shown in FIG. 5D in accordance with another embodiment, the control unit 180 of the solder ball attaching apparatus may close the vacuum valve 166 and open the spray valve 176 to provide air to the vacuum line 164, the common line 106, the nozzle 104, the pores 122 of the porous plate 120, and the holes 132. By opening the spray valve 176 to provide air, a driving force dropping to the pad 310 may increase.

Although not shown in detail, the solder balls SDBs mounted on the pads 310 on which the flux FLX is dotted may be adhered on the pads 310 through a reflow process.

Hereinafter, a cleaning process using the solder ball attaching apparatus is simply described.

In the solder ball attaching apparatus as described in FIGS. 1A through 1C, by closing the vacuum valve 166 and opening the spray valve 176 to provide air or de-ionized water, it is possible to remove foreign materials remaining on the mask pattern 130 and the bottom surface of the porous plate 120. When removing the foreign materials remaining on the bottom surface of the porous plate 120, the removal operation may be performed after the separation of the mask pattern 130.

Also, by closing the vacuum valve 166 and opening the spray valve 176 to provide air or deionized water, foreign materials remaining on the substrate or in equipment may be removed. In this case, the removing operation may be performed after the separation of the mask pattern 130.

According to some embodiments of the inventive concepts, it is possible to reduce the costs of consumables in the solder ball attaching apparatus by using the porous plate 120 and the mask pattern 130. Also, it is possible to accurately place the solder balls SDBs on targeted locations by using the mask pattern 130 having holes formed by using LASER.

While embodiments of the inventive concept are described with reference to the accompanying drawings, a person skilled in the art may understand that the inventive concept may be practiced in other particular forms without changing technical spirits or essential characteristics. Therefore, embodiments described above should be understood as illustrative and not limitative in every aspect.

1. A solder ball attaching apparatus comprising:
a porous plate; and
a mask pattern on a surface of the porous plate, the mask pattern comprising holes configured to temporarily store solder balls therein.

2. The solder ball attaching apparatus of claim 1, wherein the porous plate comprises pores having a size of about 1 μm to about 50 μm.

3. The solder ball attaching apparatus of claim 1, wherein the porous plate comprises pores having a size of about 10 μm to about 15 μm.

4. The solder ball attaching apparatus of claim 1, wherein the porous plate comprises pores having a substantially uniform size.

5. The solder ball attaching apparatus of claim 1, wherein the porous plate comprises at least one of zeolite, cement, ceramic, porous plastic, and porous metal.

6. The solder ball attaching apparatus of claim 1, wherein the mask pattern is removably coupled to the porous plate.

7. The solder ball attaching apparatus of claim 1, wherein a size of each of the holes of the mask pattern is substantially the same as or larger than a size of each of the solder balls.

8. A solder ball attaching apparatus comprising:
a housing;
a porous plate on a bottom surface of the housing;
a mask pattern on a bottom surface of the porous plate and having holes which provide spaces configured to temporarily store solder balls therein; and
a vacuum unit configured to provide a vacuum force to the porous plate.

9. The solder ball attaching apparatus of claim 8, wherein the porous plate is removably coupled to the housing, and
the mask pattern is removably coupled to the porous plate.

10. The solder ball attaching apparatus of claim 8, wherein the porous plate comprises pores having a size of about 10 μm to about 15 μm.

11. The solder ball attaching apparatus of claim 8, wherein the housing comprises:
nozzles in the housing, each of the nozzles having one end opening toward the porous plate; and
a common line communicating with another end of the nozzles.

12. The solder ball attaching apparatus of claim 11, wherein the vacuum unit comprises:
a vacuum pump;
a vacuum line connecting the vacuum pump to the common line; and
a vacuum valve on the vacuum line.

13. The solder ball attaching apparatus of claim 12, further comprising a control unit connected to the vacuum valve and controlling opening and closing of the vacuum valve.

14. The solder ball attaching apparatus of claim 11, further comprising a spray unit providing air or water to the porous plate.

15. The solder ball attaching apparatus of claim 14, wherein the spray unit comprises:
a fan;
a spray line connecting the fan to the common line; and
a spray valve on the spray line.

16. The solder ball attaching apparatus of claim 15, further comprising a control unit connected to the spray valve, the control unit configured to control opening and closing of the spray valve.

17. The solder ball attaching apparatus of claim 14, further comprising a control unit connected to the spray unit and the vacuum unit to control the spray unit and the vacuum unit.

18-20. (canceled)

21. A solder ball attaching apparatus comprising:
a housing comprising:
a body having nozzles;
a porous plate having pores disposed within the porous plate; and
a mask pattern on a bottom surface of the porous plate, the mask pattern comprising holes,
each of the holes being in communication with at least some of the plurality of the pores in a way that a vacuum force can be substantially uniformly applied to solder balls when the solder bolls are placed in the holes to mount the solder balls on to a substrate.

22. The apparatus of claim 21, wherein the mask pattern comprise a plurality of patterns each including an upper portion having a first width and a lower portion having a second width smaller than the first width, and wherein an upper width of a hole defined between adjacent two patterns among the plurality of patterns is smaller than a lower width thereof.

23. The apparatus of claim 21, wherein the nozzles, the pores in the porous plate, and the hole communicate with one another.
